(19) United States
(12) Patent Application Publication
(10) Pub. No.: US 2023/0080926 A1
(43) Pub. Date: Mar. 16, 2023

(54) PHOTOELECTRIC CONVERSION PANEL AND X-RAY PANEL

(71) Applicant: Sharp Display Technology Corporation, Kameyama City (JP)

(72) Inventor: Fumiki NAKANO, Kameyama City (JP)

(21) Appl. No.: 17/939,435

(22) Filed: Sep. 7, 2022

(30) Foreign Application Priority Data
Sep. 14, 2021 (JP) 2021-149780

(51) Int. Cl. H01L 27/146; G01T 1/20

(52) U.S. Cl. CPC H01L 27/14623; H01L 27/14663; H01L 27/14636; G01T 1/2018

(57) ABSTRACT

A photoelectric conversion panel includes multiple thin-film transistors (TFTs), multiple photodiodes respectively connected the TFTs, a bias line, and a light shielding layer that is formed in a position overlapping at least one of the photodiodes in a plan view. One of the TFTs connected to a photodiode includes an electrically conductive region that connects a drain electrode of the TFT to a source electrode of the TFT.

### BACKGROUND

### 1. Field

The present disclosure relates to a photoelectric conversion panel and an X-ray panel.

### 2. Description of the Related Art

Photoelectric conversion panel and X-ray panels are disclosed. For example, U.S. Pat. No. 10,962,660 discloses a photoelectric conversion panel and an X-ray panel.

The X-ray panel disclosed in U.S. Pat. No. 10,962,660 includes photoelectric conversion elements (photodiode) arranged in a pixel region, a protection circuit arranged in a region outside the pixel region, a bias line connected to the photoelectric conversion elements, a wiring connected to the protection circuit, and a bias terminal supplying the bias line with a bias voltage. The protection circuit is arranged between the bias terminal and the pixel region. The wiring connected to the protection circuit is supplied with a voltage higher than the bias voltage supplied to the bias line and protects elements on the X-ray panel from static electricity.

In the X-ray panel (photoelectric conversion panel) disclosed in U.S. Pat. No. 10,962,660, if the region between the bias terminal and the pixel region (region outside the pixel region) is smaller in area, it may be difficult to arrange the protection circuit. To operate the protection circuit, a power supply may be separately arranged for the protection circuit. There is a demand for a photoelectric conversion panel and an X-ray panel that are, even with a smaller region outside the pixel region (outside region), capable of protecting elements on the X-ray panel from electrostatic discharge (ESD) and are free from a power supply for the protection circuit.

It is desirable to provide a photoelectric conversion panel and an X-ray panel, even with a smaller outside region, capable of protecting elements on the X-ray panel from ESD and free from a power supply for a protection circuit.

### SUMMARY

According to a first aspect of the disclosure, there is provided a photoelectric conversion panel including: a substrate; a plurality of transistors formed in a pixel region of the substrate; a plurality of photodiodes arranged on the pixel region and respectively connected to the transistors; a bias line connected to the photodiodes; and a light shielding layer covering part of the pixel region wherein one of the transistors connected to at least one of the photodiodes arranged in a position overlapping the light shielding layer includes an electrically conductive region that connects a drain electrode of the transistor to a source electrode of the transistor.

According to a second aspect of the disclosure, there is provided an X-ray panel including: the photoelectric conversion panel according to the first aspect; a scintillator that emits fluorescence when the scintillator is irradiated with X rays, wherein the light shielding layer is arranged between the photodiodes and the scintillator.

### BRIEF DESCRIPTION OF IRE DRAWINGS

FIG. 1 schematically illustrates an X-ray imaging apparatus including an X-ray panel including a photoelectric conversion and of a first embodiment;

FIG. 2 is a plan view illustrating a configuration of the photoelectric conversion panel;

FIG. 3 illustrates a structure of a light shielding region in a pixel region;

FIG. 4 is a plan view of a pixel arranged in an imaging region;

FIG. 5 is a plan view of a pixel arranged in the light shielding region;

FIG. 6 is a cross-sectional view of a border region between the imaging region and the light shielding region in the photoelectric conversion panel;

FIG. 7 is a plan view of a photoelectric conversion panel in an X-ray imaging apparatus of a second embodiment;

FIG. 8 is a cross-sectional view of part of the photoelectric conversion panel of the second embodiment; and

FIG. 9 is a cross-sectional view of a photoelectric conversion panel of an X-ray imaging apparatus of a third embodiment.

### DESCRIPTION OF THE EMBODIMENTS

Embodiments of the disclosure are described with reference to the drawings. The disclosure is not limited to the embodiments described below. The embodiments may be appropriately modified without departing from the scope of the disclosure. In the discussion that follows, like elements or elements having the same function are designated with the same reference numerals throughout different drawings and the discussion thereof are not repeated. Configurations in the embodiments and modifications of the embodiments may be combined or changed without departing from the scope of the disclosure. For easier understanding, the configurations may be simplified or clarified in the drawings, and some of components in each configuration may be omitted. The components in the drawings are not necessarily drawn to scale.

### First Embodiment

Configuration of X-Ray imaging Apparatus

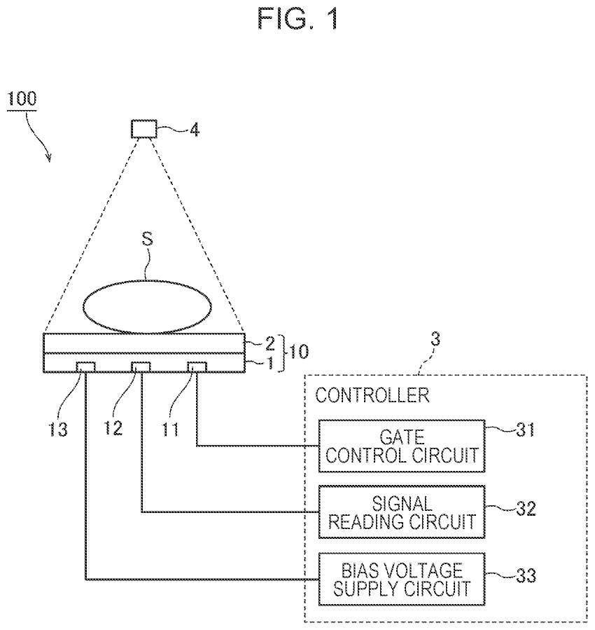

FIG. 1 schematically illustrates an X-ray imaging apparatus 100 including an X-ray panel 10 including a photoelectric conversion panel 1 of a first embodiment. The X-ray imaging apparatus 100 include the X-ray panel 10 including the photoelectric conversion pane 1 and a scintillator 2, a controller 3, and an X-ray source 4.

Referring to FIG. 1, the controller 3 includes a gate control circuit 31, a signal reading circuit 32, and a bias voltage supply circuit 33. The gate control circuit 31 is connected to a gate terminal 11 of the photoelectric conversion panel 1. The signal reading circuit 32 is connected to a data terminal 12. The bias voltage supply circuit 33 is connected to a bias terminal 13.

The X-ray source 4 emits X rays to a subject S. X rays transmitted through the subject S are converted into fluorescence (hereinafter referred to as “scintillation light”) by the scintillator 2 placed on the photoelectric conversion panel 1. The X-ray imaging apparatus 100 generates an X-ray image by picking up the scintillation light with the X-ray panel 10.

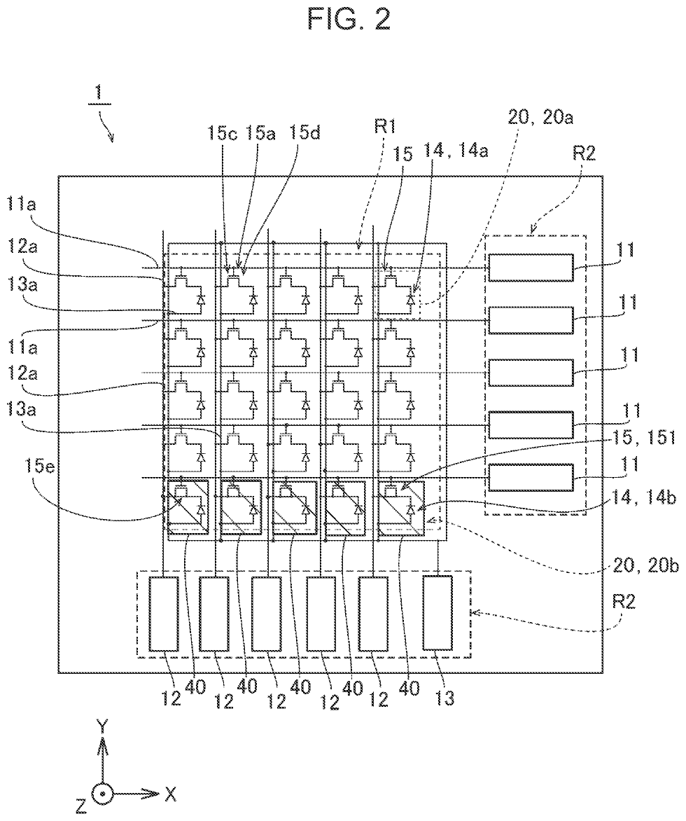

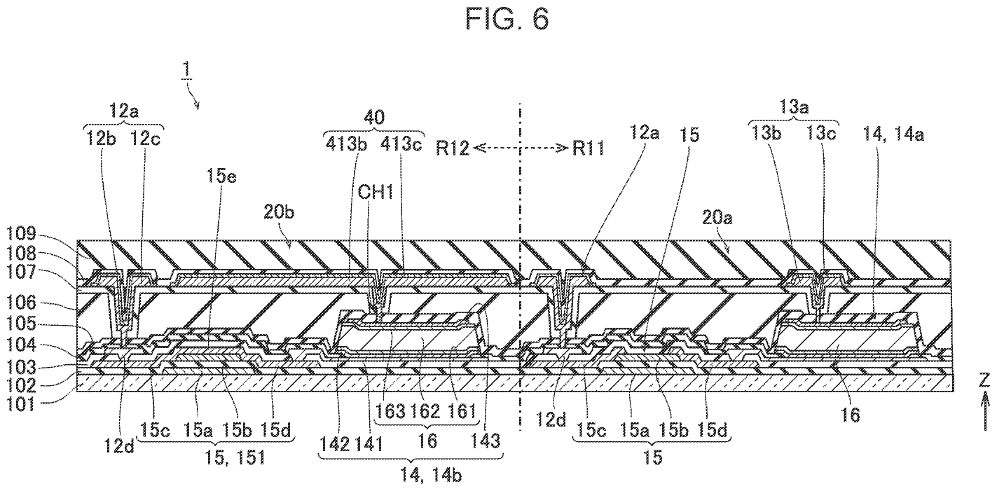

FIG. 2 is a plan view schematically illustrating the photoelectric conversion pane 1. The photoelectric conversion panel 1 includes multiple gate terminals 11, multiple data terminals 12, a bias terminal 13, multiple photodiodes 14, multiple thin-film transistors (TFTs) 15, and light shielding layers 40. Formed on a substrate 101 (see FIG. 6) of the photoelectric conversion panel 1 are multiple gate lines 11a, multiple data lines 12a, and a bias line 13a.

The gate lines 11a connects gate electrodes 15a of the TFTs 15 to the gate terminals 11. The data lines 12a connect source electrodes 15c of the TFTs 15 to the data terminals 12. The bias lines 13a are connected to the bias terminal 13, multiple photodiodes 14, and light shielding levers 40.

Referring to FIG. 2, the photoelectric conversion panel 1 includes a pixel region R1 and terminal regions R2. The pixel region R1 is rectangular in a plan view. The pixel region R1 includes multiple pixels 20 defined by multiple gate lines 11a and multiple data lines 12a. The terminal regions R2 are respectively formed on a positive side of the pixel region R1 in an X direction and on a negative side of the pixel region R1 in a Y direction and the gate terminals 11, the data terminals 12 and the bias terminal 13 are formed on the terminal regions 12.

Referring to FIG. 2, the gate lines 11a and the data lines 12a are formed in the pixel region R1 such that the gate lines 11a intersect the data lines 12a. Multiple pixels 20 are thus arranged in a matrix in a plan view. For example, bias lines 13a and light shielding layers 40 are formed along the data lines 12a. Each pixel 20 includes a photodiode 14 and a TFT 15. The photodiodes 14 and the TFTs 15 are respectively arranged in the pixels 20.

Referring to FIG. 2, the gate terminals 11 are arrange side by side in the Y direction in the terminal region R2. The data terminals 12 and the bias terminal 13 are arranged side by side in the X direction in the terminal region R2. The gate terminals 11 convey gate signals from the gate control circuit 31 to the gate lines 11a. The data terminals 12 apply voltage read from the signal reading circuit 32 to the data lines 12a. The data terminals 12 also acquire data signals from the photodiodes 14 via the data lines 12a and the TFTs 15 and convey the acquired data signals to the signal reading circuit 32. The bias terminal 13 supplies a bias voltage from the bias voltage supply circuit 33 to the bias lines 13a.

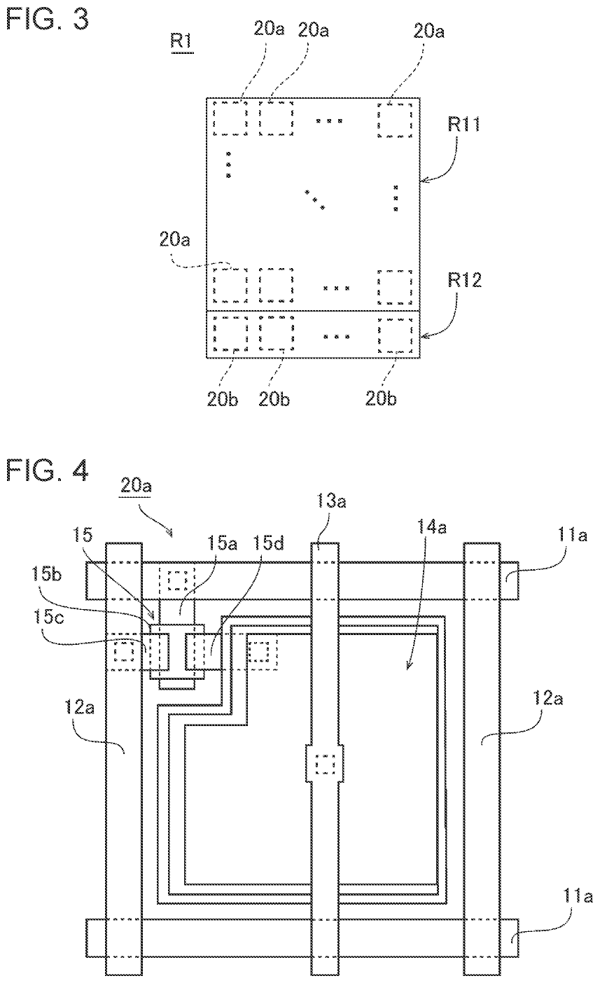

FIG. 3 illustrates the configuration of the light shielding region R12 in the pixel region R1. Referring to FIG. 3, the pixel region R1 includes the imaging region R11 and the light shielding region R12 arranged closer to the data terminal 12 than the imaging region R11. The pixels 20 include pixels 20a arranged in the imaging region R11 and pixels 20b arranged in the light shielding region R12. The pixel 20a is used to receive light for image capturing. The pixel 20b is a dummy pixel not used for image capturing. In other words, the imaging region R11 is an active region.

The controller 3 in FIG. 1 causes the X-ray source 4 to radiate X rays and generates an X-ray image in response to a data signal acquired from the signal reading circuit 32. The photodiodes 14 include photodiodes 14a arranged in the imaging region R11 and photodiodes 14b arranged in the light shielding region R12. For example, the photodiode 14a, when supplied with a bias voltage from the bias line 13a, converts X rays transmitted through the subject S into charge responsive to an amount of scintillation light converted by the scintillator and transfers a signal responsive to the charge (data signal) to the TFT 15. The controller 3 causes the gate control circuit 31 to supply selectively and successively the gate lines 11a with the gate signals. The TFT 15, when supplied with the gate signal, turns on. The data line 12a is supplied with a read voltage by the signal reading circuit 32, and when the TFT 15 turns on, a signal (data signal) responsive to charge converted by the photo diode 14a is added to the read signal. The signal reading circuit 32 thus acquires the data signal. The controller 3 generates an X-ray image in accordance with the data signal of each pixel 20a in the imaging region R11.

### Structure of Light Shielding Layer

Referring to FIG. 2, the light shielding layer 40 is formed in a position overlapping the photodiode 14b in a plan view. By reflecting or absorbing at least part of the scintillation light traveling from the scintillator 2 to the photodiode 14b, the light shielding layer 40 shields from light the photodiode 14b arranged in the overlapping position in the plan view.

The light shielding layer 40 is manufactured of a metallic material having light-shielding properties. For example, the metallic material contains at least one component selected from the group consisting of titanium Ti, aluminum Al, and copper Cu. According to the first embodiment, the light shielding layer 40 and the bias line 13a are integrated into a unitary body and thus manufactured of the same material and formed in the same layer. Referring to FIG. 2, the light shielding layer 40 is arranged to cover the photodiode 14b of the pixel 20b and the bias line 13a is connected to the photodiode 14a of the pixel 20a. The bias line 13a is connected to the photodiode 14b of the pixel 20b via the light shielding layer 40.

Referring to FIGS. 2 and 3, for convenience of explanation, the light shielding layers 40 are formed in positions overlapping an outermost row of photodiodes 14b out of the photodiodes 14 arranged in a matrix. The disclosure is not limited to this configuration. For example, the light shielding layers 40 may be formed in positions overlapping several dozens of outermost columns and several dozens of outermost rows of the photodiodes 14b out of the photodiodes 14 arranged in a matrix.

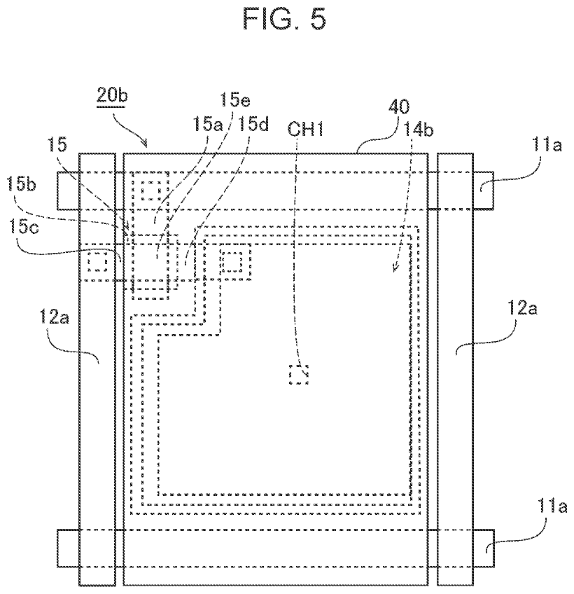

FIG. 4 is a plan view of the pixel 20a arranged in the imaging region R11. FIG. 5 is a plan view of the pixel 20b arranged in the light shielding region R12. FIG. 6 is a cross-sectional view of a border region between the imaging region R11 and the light shielding region R12 in the photoelectric conversion panel 1. As illustrated in FIGS. 4 and 6, in the pixel 20a, a portion of the photodiode 14a is arranged in a position overlapping the bias line 13a in a plan view but the remaining portion of the photodiode 14a is not light-shielded. Referring to FIGS. 5 and 6, the light shielding layer 40 covers the entire photodiode 14b and at least part of the TFT 15 in the pixel 20b. The light shielding layer 40 is formed to be spaced apart from the data line 12a. The light shielding layer 40 and the data line 12a are not short-circuited.

Referring to FIG. 6, the bias line 13a includes only a lower bias electrode 13b or both the lower bias electrode 13b and an upper bias electrode 13c. The light shielding layer 40 includes only a lower layer 413b or both the lower layer 413b and an upper layer 413c. The lower layer 413b is formed in the same layer as the lower bias electrode 13b. The upper layer 413c is formed in the same layer as the upper bias electrode 13c. The light shielding layer 40 is connected to the photodiode 14b arranged in the light shielding region R12 via a contact hole CH1. The light shielding layer 40 thus operates as a bias line for the photodiode 14b. Referring to FIG. 6, the bias line 13a includes the lower bias electrode 13b and the upper bis electrode 13c. The disclosure is not limited to this configuration. For example, the bias line 13a may include only one layer (such as only the lower bias electrode 13b) or three or more layers. Referring to FIG. 6, the light shielding layer 40 includes the lower layer 413b and the upper layer 413c. The disclosure is not limited to this configuration. The light shielding layer 40 may include only one layer (for example, only the lower layer 413b) or three or more electrically conductive films.

Each of the photodiodes 14a and 14b includes a first lower electrode 141, a second lower electrode 142, an upper electrode 143, and a photoelectric conversion layer 16. The photoelectric conversion layer 16 is interposed between the second lower electrode 142 and the upper electrode 143. In the imaging region R11, scintillation light converted by the scintillator 2 (see FIG. 1) arranged more positive side in a Z direction than the photoelectric conversion panel 1 is incident on the photoelectric conversion layer 16 and converted into charge by the photoelectric conversion layer 16. In the light sh1Pldlng region R12, the scintillation light is shielded by the light shielding layer 40 and no scintillation light is thus incident on the photodiode 14b.

### Structure of TFT

Referring to FIG. 6, the TFT 15 includes the gate electrode 15a, a semiconductor active layer 15b, a source electrode 15c, and a drain electrode 15d. The drain electrode 15d is connected to the second lower electrode 142 via the first lower electrode 141. The data line 12a includes two layers, specifically, a lower data electrode 12b and an upper data electrode 12c. The data line 12a is connected to the source electrode 15c via a joint electrode 12d. The bias line 13a includes two layers, specifically, the lower bias electrode 13b and the upper bias electrode 13c. The bias line 13a is connected to the upper electrode 143.

### Materials of Layers and Positional Relationship of Layers

Referring to FIG. 6, the photoelectric conversion panel 1 includes the substrate 101, and a first insulator film 102 through an eighth insulator film 109. The gate electrode 15a is formed on the substrate 101. The substrate 101 is electrically insulative. The gate electrode 15a is formed as a lamination film manufactured of tungsten W and tantalum nitride TaN. The first insulator film 102 covers the gate electrode 15a. The first insulator film 102 is formed by laminating an insulator film of silicon oxide SiO₂ as an upper layer and an insulator film of silicon nitride SiNₓ as a lower layer. The semiconductor active layer 15b, the source electrode 15c, and the drain electrode 15d are formed on or above the gate electrode 15a with the first insulator film 102 interposed therebetween.

The semiconductor active layer 15b is manufactured of oxide semiconductor. The oxide semiconductor may be InGaO3(ZnO)5, magnesium oxide zinc MgxZn1-xO, cadmium oxide zinc CdxZn1-xO, cadmium oxide CdO, InSnZnO (containing indium In, tin Sn, and zinc Zn), indium In-aluminum Al-zinc Zn-oxygen O based semiconductor, or amorphous oxide semiconductor containing indium In, gallium Ga and zinc Zn at a predetermined ratio. The oxide semiconductor may be an amorphous material or a crystalline material (such as a polycrystal material, a microcrystal material, or a c-axis oriented material). In the case of a lamination structure, any combination of materials is acceptable (any specific combination is not excluded). According to the first embodiment, the semiconductor active layer 15b is amorphous oxide semiconductor containing indium In, gallium Ga, and zinc Zn at a predetermined ratio. The semiconductor active layer 15b, if manufactured of oxide semiconductor IGZO containing indium In, gallium Ga, zinc Zn, and oxygen O, may reduce a leakage current of the TFTs 15, leading to a higher signal to noise (S/N) ratio than amorphous silicon a-Si. A higher sensitivity sensor may thus result.

Referring to FIG. 6, the source electrode 15c and the drain electrode 15d are formed on the same layer. The source electrode 15c and the drain electrode 15d have a three-layer lamination structure by interposing a metal film of aluminum Al between two metal films of titanium Ti.

According to the first embodiment, the TFT 15 connected to the photodiode 14b (hereinafter referred to as “TFT 151”) includes an electrically conductive region 15e that connects the drain electrode 15d connected to the photodiode 14b to the source electrode 15c. The electrically conductive region 15e causes the TFT 151 to stop working as a switching element. In this way, static electricity is allowed to flow via the TFT 151 between the photodiode 14b and the data line 12a. The electrically conductive region 15e is formed in the same layer as the drain electrode 15d and the source electrode 15c and manufactured of the same material as the drain electrode 15d and the source electrode 15c. The electrically conductive region 15e, the drain electrode 15d, and the source electrode 15c are integrated into a unitary body.

A second insulator film 103 (passivation film) is formed as an upper film on or above the first insulator film 102 in a manner such that the second insulator film 103 covers the source electrode 15c, the drain electrode 15d, and the electrically conductive region 15e. For example, the second insulator film 103 is manufactured of silicon oxide SiO₂.

The first lower electrode 141 and the joint electrode 12d are formed in a layer on or above the second insulator film 103. The first lower electrode 141 and the joint electrode 12d have a three-layer lamination structure that is formed by interposing a metal film of aluminum Al between two metal films of titanium Ti. The third insulator film 104 is formed to cover part of the first lower electrode 141 and part of the second insulator film 103. The second lower electrode 142 is formed to cover part of the first lower electrode 141. For example, the second lower electrode 142 is manufactured of titanium Ti.

The photoelectric conversion layer 15 is formed on the second lower electrode 142. The photoelectric conversion layer 16 is formed by laminating an n-type amorphous semiconductor layer 161, an intrinsic amorphous semiconductor layer 162, and a p-type amorphous semiconductor layer 163 in that order. The n-type amorphous semiconductor layer 161 is manufactured of amorphous silicon that is doped with an n-type impurity (such as phosphorus). The intrinsic amorphous semiconductor layer 162 is manufactured of intrinsic amorphous silicon. The intrinsic amorphous semiconductor layer 162 is formed in contact with the n-type amorphous semiconductor layer 161. The p-type amorphous semiconductor layer 163 is manufactured of amorphous silicon that is doped with a p-type impurity (such as boron). The p-type amorphous semiconductor 1ayer 163 is formed in contact with the intrinsic amorphous semiconductor layer 162. The disclosure is not limited to this lamination order. For example, the lamination order of n-type semiconductor (+n), intrinsic semiconductor (i), and p-type semiconductor (+p) may be +p/i/+n or +n/i/+p. The upper electrode 143 is formed on or above the photoelectric conversion layer 16. The upper electrode 143 is manufactured of indium tin oxide ITO.

The fourth insulator film 105 is formed to cover at least part of each of the photodiode 14 and the third insulator film 104. The fourth insulator film 105 covers the side surface of the photodiode 14 and part of the top surface of the photodiode 14. The fourth insulator film 105 is manufactured of silicon nitride SiNₓ.

The fifth insulator film 106 covers at least part of the fourth insulator film 105. The fifth insulator film 106 is a planarization film that covers the photodiode 14 and planarizes steps formed by the photodiode 14. For example, the fifth insulator film 105 is manufactured of an organic material. The sixth insulator film 107 is an inorganic film that covers part of the fifth insulator film 106. The data line 12a, the bias line 13a, and the light shielding layer 40 are formed on the sixth insulator film 107. The lower data electrode 12b of the data line 12a, the lower bias electrode 13b of the bias line 13a, and the lower layer 413b of the light shielding layer 40 have a three-layer lamination structure that is formed by interposing a metal film of aluminum Al between two metal films of titanium Ti. For example, the upper data electrode 12c of the data line 12a, the upper etas electrode 13c of the bias line 13a, and the upper layer 413c of the light shielding layer 40 are manufactured of, for example, ITO.

The seventh insulator film 108 is formed to cover the data line 12a, the bias line 13a, and the light shielding layer 40. For example, the seventh insulator film 108 is manufactured of silicon nitride SiNₓ. The eighth insulator film 109 covers the seventh insulator film 108. For example, the eighth insulator film 109 is manufactured of an organic material.

The light shielding layer 40 is formed on or above the photodiode 14b in the light shielding region R12 (on a light incident side of the photoelectric conversion panel 1). The light shielding layer 40 is not formed in the imaging region R11. The scintillator 2 is formed on or above the eighth insulator film 109. Specifically, the light shielding layer 40 is formed between the photodiode 14b and the scintillator 2. The light shielding layer 40 is also formed in a position overlapping the TFT 151 in a plan view in the light shielding region R12. This arrangement may reduce an effect of light and X rays to the TFT 151.

In the configuration of the first embodiment, the electrically conductive region 15e short-circuits the two ends of the TFT 151. Upon entering the data line 12a or the photodiode 14b, each connected to the TFT 151, static electricity may be drained through the TFT 151 and the photodiode 14b. As a result, the photodiode 14b may operate as an electrostatic discharge (ESD) protection device of the data line 12a. Since the photodiode 14b is arranged in a position overlapping the light shielding layer 40, no leakage current may occur in response to light and the output of the photoelectric conversion panel 1 may be unaffected by an output from the photodiode 14b. The photodiode 14 arranged within the pixel region R1 may thus be used as a protection device. Even when a region outside the pixel region R1 (outside region) is smaller in area, the elements on the photoelectric conversion panel 1 may be protected from static electricity. Since the photodiode 14b used as the protection circuit is supplied with a bias voltage from the bias line 13a and the light shielding layer 40, no power supply is involved for the protection circuit. Unlike when a transistor having a lower threshold voltage is used as a protection device, the photodiode 14b used as a protection device controls any effect on a captured image while protecting the elements on the photoelectric conversion panel 1 from static electricity. Even the use of the TFT 151 having a lower threshold voltage (Vth) as a switching element for the pixel 20a may lead to a photoelectric conversion panel 1 that may be robust against static electricity and free from an imaging failure caused by a current flowing through a protection device during imaging.

Since the pixel 20b is a dummy pixel not used for image capturing, the photodiode 14b arranged in the dummy pixel may be used as a protection device. As a result, the photoelectric conversion panel 1 is free from arranging a new photodiode 14b to be used as the protection device.

### Second Embodiment

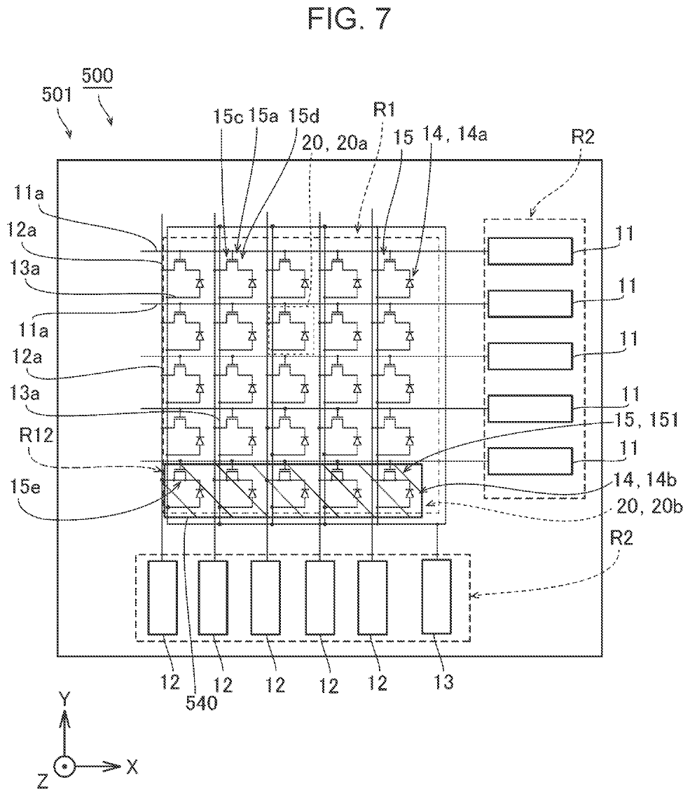

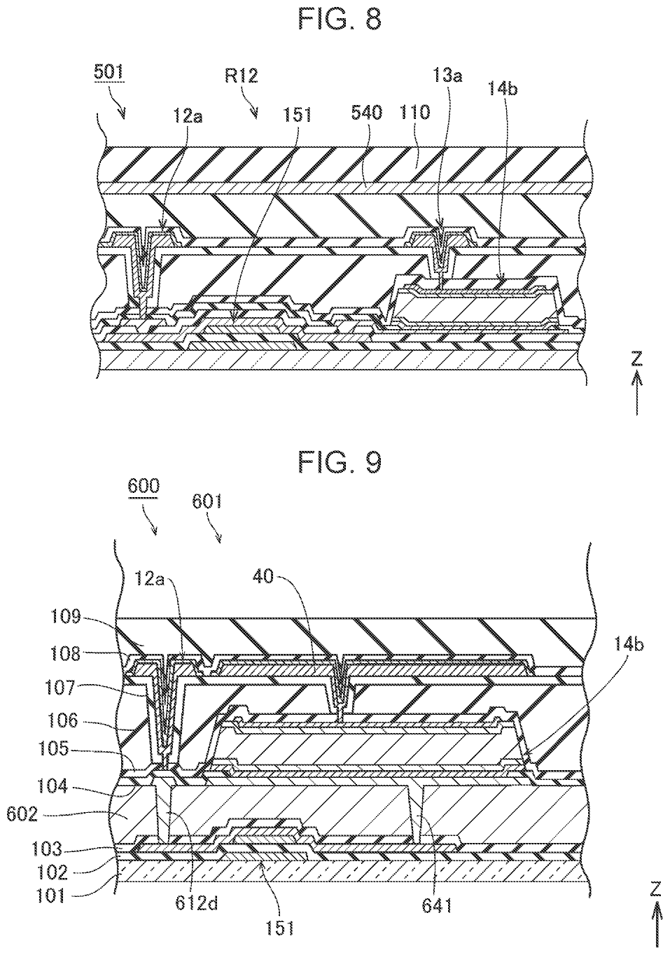

The configuration of an X-ray imaging apparatus 500 of a second embodiment is described below with reference to FIGS. 7 and 8. FIG. 7 is a plan view of a photoelectric conversion panel 501 in the X-ray imaging apparatus 500 of the second embodiment. FIG. 8 is a cross-sectional view of part of the photoelectric conversion panel 501 of the second embodiment. Elements identical to those in the first embodiment are designated with the same reference numerals and the discussion thereof is omitted herein.

Referring to FIG. 7, the photoelectric conversion panel 501 in the X-ray imaging apparatus 500 of the second embodiment includes a light shielding layer 540. The light shielding layer 540 is formed in a position overlapping in a plan view the photodiodes 14b arranged in the light shielding region R12. The light shielding layer 540 is so formed as to cover the entire light shielding region R12.

In the second embodiment as illustrated in FIG. 8, the light shielding layer 540 is formed on or above the data line 12a and the bias line 13a. The photodiode 14b in the second embodiment is directly connected to the bias line 13a. The photoelectric conversion panel 501 includes an insulator layer 110 covering the light shielding layer 540. For example, the light shielding layer 540 contains a material having light-shielding properties (i.e., material containing Ti). The insulator layer 110 is manufactured of an organic material.

Unlike the first embodiment in which spacing is implemented between the data line 12a and the light shielding layer 40 in order to insulate the data line 12a from the light shielding layer 40 (the light shielding layer in the first embodiment), the light shielding layer 540 covers the entire light shielding region R12 in the second embodiment. The light shielding performance to the photodiodes 14b may be better than in the first embodiment. As a result, the leakage current to the photodiodes 14b may be controlled more. Since the light shielding layer 540 and the data line 12a are formed in different layers, short-circuit between the light shielding layer 540 and the data line 12a may be controlled. The rest of the configuration and effect remain unchanged from those of the first embodiment.

### Third Embodiment

The configuration of an X-ray imaging apparatus 600 of a third embodiment is described with reference to FIG. 9. FIG. 9 is a cross-sectional view of part of a photoelectric conversion panel 601 in the X-ray imaging apparatus 600 of the third embodiment. Elements in the third embodiment identical to those in the first and second embodiments are designated with the same reference numerals and the discussion thereof is omitted herein.

In the photoelectric conversion panel 601 in the X-ray imaging apparatus 600 of the third embodiment, as illustrated in FIG. 9, a planarization film 602 is formed below the photodiode 14b and above the TFT 151. The planarization film 602 is so formed as to cover the second insulator film 103 (passivation film) covering the TFT 151. The planarization film 602 planarizes steps on the top surface of the second insulator film 103 caused by the TFT 151. The photodiode 14b is connected to the TFT 151 via a lower electrode 641 formed in a contact hole in the planarization film 602. The data line 12a is connected to the TFT 151 via a joint electrode 612d formed in a contact hole in the planarization film 602. With the planarization film 602, the photodiode 14b and the TFT 151 may be arranged in an overlapping position. As a result, since the photodiode 14b is arranged beyond the TFT 151, an area of the photodiode 14b per pixel may be increased. According to the third embodiment, a protection device having a higher ESD withstand voltage may be formed. The rest of the configuration and effect remain unchanged from those of the first and second embodiments.

The embodiments have been described for exemplary purposes only. The disclosure is not limited to the embodiments described above. The embodiments may be appropriately modified without departing from the scope and spirit of the disclosure.

(1) According to the first through third embodiments, the light shielding layer is a metallic layer. The disclosure is not limited to the metallic material. For example, the light shielding layer may be manufactured of a material that is not metallic and has light-shielding properties (for example, an organic material or an inorganic material).

(2) According to the first through third embodiments, the photoelectric conversion panel is applied to the X-ray panel of the X-ray imaging apparatus. Alternatively, the photoelectric conversion panel may be applied to a light sensor panel.

(3) According to the first through third embodiments, the layers (films) forming the photoelectric conversion panel are described above. Alternatively, the layers (films) of the photoelectric conversion panel may be layers (films) other than those described above.

The photoelectric conversion panel and the X-ray panel may also be described below.

According to a first configuration, there is provided a photoelectric conversion panel including a substrate; a plurality of transistors formed in a pixel region of the substrate; a plurality of photodiodes arranged on the pixel region and respectively connected to the transistors; a bias line connected to the photodiodes; and a light shielding layer covering at least part of the pixel region, wherein one of the transistors connected to at least one of the photodiodes arranged in a position overlapping the light shielding layer includes an electrically conductive region that electrically connects a drain electrode of the transistor to a source electrode of the transistor (first configuration).

According to the first configuration, the transistor having the electrically conductive region allows the two ends of the transistor to be short-circuited via the electrically conductive region. Even when static electricity enters the bias line connected to the transistor or at least one of the photodiodes arranged in a position overlapping the light shielding layer, the static electricity may be drained through the transistor or the photodiode. As a result, at least one of the photodiodes arranged in a position overlapping the light shielding layer may operate as a protection device. Since the photodiode operating as the protection device is arranged in a position overlapping the light shielding layer, a leakage current caused by light is less likely to occur. The output from the photodiode operating as the protection device is less likely to affect the output from the photoelectric conversion panel. If the region outside the pixel region (the outside region) is smaller in area, at least one of the photodiodes arranged in the pixel region may be used as a protection device. At least one of the photodiodes arranged in a position overlapping the light shielding layer is used as the protection device. Unlike when a protection device is separately arranged, the photoelectric conversion panel is free from using a power supply for the protection circuit.

Instead of the photodiode in the pixel region, the transistor may be used as the protection device. The transistor may also have a lower threshold voltage. In such a case, even a smaller voltage difference between a gate electrode and a source electrode may not cause the transistor to turn off and thus a current may still continue to flow. If a current flows through the transistor, a captured image may be affected. In contrast, since the photodiode is used as the protection device in the first configuration, the elements on the photoelectric conversion panel may be protected from static electricity while any effect on the captured image may be controlled. The use of the TFT having a lower threshold voltage (Vth) as a switching element for a pixel may lead to a photoelectric conversion panel that may be robust against static electricity and free from an imaging failure caused by a current flowing through a protection device during imaging.

According to the first configuration, the photodiodes may be arranged in a matrix on the substrate and the light shielding layer may be formed in a position overlapping in a plan view at least one of the photodiodes, arranged in an external edge region of the substrate, out of the photodiodes (second configuration).

If multiple pixels (photodiodes and transistors) are arranged in a matrix, pixels in an external edge portion are more likely to be damaged. The pixels in the external edge portion are arranged on the substrate as dummy pixels instead of being used for image capturing. According to the second configuration, since at least one of the photodiodes arranged as the dummy pixels is used as the protection device, the photoelectric conversion panel is free from arranging a new photodiode as the protection device.

According to the first or second configuration, the photoelectric conversion panel may further include a data line connected to the source electrode; and a data terminal supplying the data line with a data signal, wherein the light shielding layer is formed in a position overlapping in a plan view at least one of the photodiodes, arranged on a portion of the pixel region facing the data terminal, out of the photodiodes (third configuration).

According to the third configuration, at least one of the photodiodes arranged in a position overlapping the light shielding layer may be used as an ESD protection device for the data line.

According to one of the first through third configurations, the light shielding layer may be connected to at least one of the photodiodes arranged in a position overlapping the light shielding layer (fourth configuration).

According to the fourth configuration, static electricity entering the light shielding layer may be drained through at least one of the photodiodes arranged in a position overlapping the light shielding layer. Static electricity entering from the transistor may be drained into the light shielding layer through at least one of the photodiodes arranged in a position overlapping the light shielding layer.

According to one of the first through fourth configurations, the light shielding layer may be formed in a layer identical to a layer of the bias line (fifth configuration).

According to the fifth configuration, since the photoelectric conversion panel is free from arranging a new layer for the light shielding layer, an increase in the number of manufacturing steps is less likely.

According to the fifth configuration, the light shielding layer is connected to the bias line (sixth configuration).

According to the sixth configuration, upon entering one of the light shielding layer and the bias line, static electricity may be drained into the other of the light shielding layer and the bias line.

According to one of the first through fourth configurations, the light shielding layer may be formed on or above the bias line (seventh configuration).

If the bias line and the light shielding layer are formed in the same layer, another wiring (such as the data line) formed in the same layer as the bias line is to be insulated from the light shielding layer. To this end, spacing is to be allowed between the light shielding layer and the wiring. According to the seventh configuration, the light shielding layer may be arranged in a position overlapping in a plan view the wiring formed in the same layer as the bias line and the light shielding layer. Without any spacing, light shielding performance to the photodiode arranged in a position overlapping the light shielding layer may be improved. As a result, the leakage current into the photodiode arranged in a position overlapping the light shielding layer may be controlled more.

According to one of the first through seventh configurations, the photoelectric conversion panel may further include a planarization film formed between a photodiode arranged in a position overlapping the light shielding layer and a transistor connected to the photodiode (eighth configuration).

According to the eighth configuration, the photodiode and the transistor may be arranged in an overlapping position with the planarization film interposed therebetween. The area of a photodiode per pixel may thus be increased. As a result, the protection device having a higher ESD withstand voltage may result.

According to a ninth configuration, there is provided an X-ray panel including the photoelectric conversion panel according to one of the first through eighth configurations; and a scintillator that emits fluorescence when the scintillator is irradiated with X rays, wherein the light shielding layer is arranged between the photodiodes and the scintillator (ninth configuration).

The X-ray panel according to the ninth configuration may protect the elements on the panel from static electricity even with a smaller outside region and may be free from using a power supply for protection circuit.

The present disclosure contains subject matter related to that disclosed in Japanese Priority Patent Application JP 2021-149780 filed in the Japan Patent Office on Sep. 14, 2021, the entire contents of which are hereby incorporated by reference.

It should be understood by those skilled in the art that various modifications, combinations, sub-combinations and alterations may occur depending on design requirements and other factors insofar as they are within the scope of the appended claims or the equivalents thereof.

What is claimed is:

1. A photoelectric conversion panel comprising:
a substrate;
a plurality of transistors formed in a pixel region of the substrate;
a plurality of photodiodes arranged on the pixel region and respectively connected to the transistors;
a bias line connected to the photodiodes; and
a light shielding layer covering at least part of the pixel region,
wherein one of the transistors connected to at least one of the photodiodes arranged in a position overlapping the light shielding layer includes an electrically conductive region that connects a drain electrode of the transistor to a source electrode of the transistor.

2. The photoelectric conversion panel according to claim 1, wherein the photodiodes are arranged in a matrix on the substrate and
wherein the light shielding layer is formed in a position overlapping in a plan view at least one of the photodiodes, arranged in an external edge region of the substrate, out of the photodiodes.

3. The photoelectric conversion panel according to claim 1, further comprising:
a data line connected to the source electrode; and
a data terminal supplying the data line with a data signal,
wherein the light shielding layer is formed in a position overlapping in a plan view at least one of the photodiodes, arranged on a portion of the pixel region facing the data terminal, out of the photodiodes.

4. The photoelectric conversion panel according to claim 1, wherein the light shielding layer is connected to at least one of the photodiodes arranged in a position overlapping the light shielding layer.

5. The photoelectric conversion panel according to claim 1, wherein the light shielding layer is formed in a layer identical to a layer of the bias line.

6. The photoelectric conversion panel according to claim 5, wherein the light shielding layer is connected to the bias line.

7. The photoelectric conversion panel according to claim 1, wherein the light shielding layer is formed on or above the bias line.

8. The photoelectric conversion panel according to claim 1, further comprising a planarization film formed between a photodiode arranged in a position overlapping the light shielding layer and a transistor connected to the photodiode.

9. An X-ray panel comprising:
the photoelectric conversion panel according to claim 1; and
a scintillator that emits fluorescence when the scintillator is irradiated with X rays,
wherein the light shielding layer is arranged between the photodiodes and the scintillator.
